(19) United States
(12) Patent Application Publication
(10) Pub. No.: US 2015/0040966 A1
(43) Pub. Date: Feb. 12, 2015

(54) PROTECTIVE COATING-ENCAPSULATED PHOTOVOLTAIC MODULES AND METHODS OF MAKING SAME

(71) Applicant: PPG Industries Ohio, Inc., Cleveland, OH (US)

(72) Inventors: Stuart D. Hellring, Pittsburgh, PA (US); Jiping Shao, Sewickley, PA (US); James E. Poole, Gibsonia, PA (US); Irina G. Schwendeman, Wexford, PA (US); Brian K. Rearick, Allison Park, PA (US); Bruce Vimelson, Valencia, CA (US); Edward R. Millero, JR., Gibsonia, PA (US); Willaim H. Retsch, Allison Park, PA (US); Debra L. Singer, Wexford, CA (US); Heather Hunter, Gibsonia, PA (US)

(73) Assignee: PPG INDUSTRIES Ohio, Inc. a corporation

(21) Appl. No.: 14/385,054

(22) PCT Filed: Mar. 14, 2013
(86) PCT No.: PCT/US2013/031239

§ 371 Date: Sep. 12, 2014

Related U.S. Application Data
(63) Continuation of application No. 13/420,081, filed on Mar. 14, 2012, now abandoned.

(30) Foreign Application Priority Data
Jan. 14, 2013 (US) PCT US2013/021369

(51) Int. Cl. H01L 31/048; H01L 31/02

(52) U.S. Cl. CPC H01L 31/0481; H01L 31/02008
USPC 136/251; 438/66

(57) ABSTRACT

Photovoltaic modules are disclosed. The photovoltaic module comprises a front transparency, a fluid encapsulant deposited on at least a portion of the front transparency, electrically interconnected photovoltaic cells applied to the fluid encapsulant and a backcoat deposited on at least a portion of the electrically interconnected photovoltaic cells. Methods of making photovoltaic modules are also disclosed.

### CROSS REFERENCE TO RELATED APPLICATION

This application is a continuation-in-part of PCT International Patent Application Serial No. PCT/US/2013/021369, filed Jan. 14, 2013 and claims priority to U.S. patent application Ser. No. 13/420,081 filed Mar. 14, 2012, which is incorporated herein by reference in its entirety.

### TECHNICAL FIELD

The present invention relates to photovoltaic modules and, more particularly, coatings useful for encapsulating such cells, and methods for making the same.

### BACKGROUND

Photovoltaic modules produce electricity by converting electromagnetic energy of the photovoltaic module into electrical energy. To survive in harsh operating environments, photovoltaic modules rely on encapsulant materials to provide durability and module life. A traditional bulk photovoltaic module comprises a front transparency, such as a glass sheet or a pre-formed transparent polymer sheet, for example, a polyimide sheet; a traditional film encapsulant, such as a film or solid sheet of ethylene vinyl acetate (“EVA”); a photovoltaic cell or cells, comprising separate wafers (i.e., a cut ingot) of photovoltaic semiconducting material, such as a crystalline silicon (“c-Si”), coated on both sides with conducting material that generate an electrical voltage in accordance with the photovoltaic effect; another layer of film encapsulant and a back sheet, such as a pre-formed polymeric sheet or film, for example, a sheet or film or multilayer composite of glass, aluminum, sheet metal (i.e., steel or stainless steel), polyvinyl fluoride, polyvinylidene fluoride, polytetrafluoroethylene, and/or polyethylene terephthalate to protect the photovoltaic cell from the environment. Photovoltaic modules are typically produced in a batch or semi-batch vacuum lamination process in which the module components are preassembled into a module preassembly. The preassembly comprises applying film encapsulant to the front transparency, positioning the photovoltaic cells and electrical interconnections onto the film encapsulant, applying an additional layer of film encapsulant onto the photovoltaic cell assembly, and applying the back sheet onto the back side of the film encapsulant to complete the module preassembly. The module preassembly is placed in a specialized vacuum lamination apparatus that uses a compliant diaphragm to compress the module assembly and cure the film encapsulant under reduced pressure and elevated temperature conditions to produce the laminated photovoltaic module. The process effectively laminates the photovoltaic cells between the front transparency and a back sheet with potting material.

While this laminated module performs acceptably, there can be processing and handling issues. The attachment of the back sheet to the cell requires a vacuum lamination curing process which can be very labor intensive and time consuming. In addition, the cells may shift during the lamination process that could generate a defect. Such laminated photovoltaic modules can also suffer premature failures from moisture ingress into the module, mainly through the edges or through the back sheet, and/or from corrosion in contact layers.

Accordingly, the need exists to replace the heavy, labor intensive and/or time consuming EVA/glass encapsulation process with a lightweight protective system that has suitable cell lifetimes by minimizing moisture ingress and/or corrosion.

### SUMMARY

In a non-limiting embodiment, a photovoltaic module is described. The photovoltaic module comprises a front transparency, a fluid encapsulant deposited on at least a portion of the front transparency, electrically interconnected photovoltaic cells applied to the fluid encapsulant and a protective coating deposited on at least a portion of the electrically interconnected photovoltaic cells.

The present invention is also directed to a method for preparing a photovoltaic module comprising applying fluid encapsulant on at least a portion of a front transparency, applying photovoltaic cells onto the fluid encapsulant, so that the cells are electrically interconnected applying a protective coating on at least a portion of the electrically interconnected photovoltaic cells, and curing the protective coating. The invention is further directed to photovoltaic modules produced in accordance with this method.

It is understood that the invention disclosed and described in this specification is not limited to the embodiments summarized in this Summary.

### BRIEF DESCRIPTION OF THE DRAWINGS

Various features and characteristics of the non-limiting and non-exhaustive embodiments disclosed and described in this specification may be better understood by reference to the accompanying figures, in which:

FIGS. 1, 2, 3 and 4 are schematic diagrams illustrating photovoltaic modules comprising protective coating systems;

FIG. 5 is a flowchart diagram illustrating a process for producing a photovoltaic module;

FIGS. 6A through 6F are schematic diagrams collectively illustrating the production of a photovoltaic module comprising the application of a two-layer protective coating system comprising a primer coating and a top coating;

FIGS. 7A and 7B show the maximum power output (Pm) change after damp heat test;

FIGS. 8A and 8B show the maximum power output (Pm) change after thermal cycling test; and

FIG. 9 shows the maximum power output (Pm) change after humidity freeze test.

The reader will appreciate the foregoing details, as well as others, upon considering the following detailed description of various non-limiting and non-exhaustive embodiments according to this specification.

### DESCRIPTION

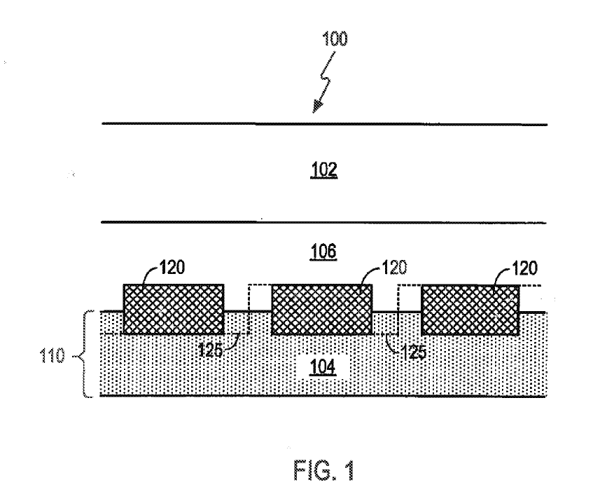

The present invention is directed to photovoltaic modules and methods of making photovoltaic modules. FIG. 1 illustrates a non-limiting and non-exhaustive embodiment of a photovoltaic module 100 that comprises a front transparency 102, a fluid encapsulant material 106 deposited on at least a portion of the front transparency 102, photovoltaic cells 120 and electrical interconnections 125 that link or connect the cells applied to the encapsulant 106 and a topcoat 104 deposited on at least a portion of the electrically interconnected photovoltaic cells 120. As used herein “front transparency” means a material that is transparent to electromagnetic radiation in a wavelength range that is absorbed by a photovoltaic cell and used to generate electricity. In embodiments, the front transparency comprises a planar sheet of transparent material comprising the outward-facing surface of a photovoltaic module. Any suitable transparent material can be used for the front transparency including, but not limited to, glasses such as, for example, silicate glasses, and polymers such as, for example, polyimide, polycarbonate, and the like, or other planar sheet material that is transparent to electromagnetic radiation in a wavelength range that may be absorbed by a photovoltaic cell and used to generate electricity in a photovoltaic module. The term “transparent” refers to the property of a material in which at least a portion of incident electromagnetic radiation in the visible spectrum (i.e., approximately 350 to 750 nanometer wavelength) passes through the material with negligible attenuation.

Fluid encapsulant material may be applied or deposited on at least a portion of the front transparency. As used herein “fluid encapsulant material” refers to fluid polymeric materials used to adhere photovoltaic cells to front transparencies and/or encapsulate photovoltaic cells within a covering of polymeric material. In various non-limiting embodiments, the fluid encapsulant material comprises a transparent fluid encapsulant, such as, for example, a clear liquid encapsulant, that is applied onto one side of the front transparency. In this example, the encapsulant is also referred to as a “front encapsulant.” As used herein to describe a fluid encapsulant the term “fluid” includes liquids, powders and/or other materials that are able to flow into or fill the shape of a space such as a front sheet. In various non-limiting embodiments, fluid encapsulant may comprise inorganic particles, such as, for example, mica. In embodiments the mica can be dispersed in the cured coat.

In embodiments the fluid encapsulant comprises a coating composition comprising at least one of a polyurethane resin, a polyurea resin, or a hybrid polyurethane-polyurea resin, or a combination of such resins. In embodiments, the fluid encapsulant comprises more than about 50% solids resin material, or about 90 to 100% solids resin material. In embodiments, the fluid encapsulant comprises about a 100% solids coating. In embodiments the fluid encapsulant has a transparency greater than 80%. In embodiments, the fluid encapulant comprises a UV curable coating. In embodiments, the fluid encapsulant comprises a liquid silicone encapsulant. In embodiments, the haze of the fluid encapsulant comprises less than 2. In embodiments the gel point of the fluid encapsulant comprises less than 20 minutes.

Photovoltaic cells 120 and electrical interconnections 125 may be positioned on the fluid encapsulant 106 so that each photovoltaic cell is electrically connected to at least one other cell. Photovoltaic cells include constructs comprising a photovoltaic semiconducting material positioned in between two electrical conductor layers, at least one of which comprises a transparent conducting material. In various non-limiting embodiments, photovoltaic cells 120 comprise bulk photovoltaic cells (e.g., ITO- and aluminum-coated crystalline silicon wafers). An assembly of photovoltaic cells 120 and electrical interconnections 125 can be used. In various other non-limiting embodiments, photovoltaic cells comprise thin-film photovoltaic cells deposited onto the encapsulant material. Thin-film photovoltaic cells typically comprise a layer of transparent conducting material (e.g., indium tin oxide) deposited onto a front transparency, a layer of photovoltaic semiconducting material (e.g., amorphous silicon, cadmium telluride, or copper indium diselenide) deposited onto the transparent conducting material layer, and a second layer of conducting material (e.g., aluminum) deposited onto the photovoltaic semiconducting material layer.

The photovoltaic modules of the present invention further comprise a protective coating 110. A “protective coating” as used herein refers to a coating that imparts at least some degree of durability, moisture barrier and/or abrasion resistance to the photovoltaic layer. The present “protective coating” can comprise one or more coating layers. The protective coating can be derived from any number of known coatings, including powder coatings, liquid coatings and/or electrodeposited coatings. It is believed that use of durable, moisture resistant and/or abrasion resistant protective coating can be used as a backing layer encapsulant material to minimize if not eliminate corrosion associated with photovoltaic cell failure.

In certain embodiments the protective coating 110 comprises a topcoat 104 applied or deposited on all or at least a portion of the photovoltaic cells 120, and any exposed encapsulant 106. The term “topcoat” as used in the context of the present invention refers to a coating layer (or series of coating layers, for instance a “base/clear” system may be collectively referred to as a “topcoat”) that has an outer surface which is exposed to the environment and an inner surface that is in contact with another coating layer or the substrate (if there is no other coating layer). The topcoat can provide an overcoat or protective and/or durable coating. In embodiments the topcoat may comprise one or more coats, wherein any coat or coats may individually comprise the same or different coating compositions. In various non-limiting embodiments described in this specification, the topcoat 104 comprises the outermost backing layer of a photovoltaic module 100, unlike the traditional photovoltaic module designs that rely on a film that is laminated and/or a back sheet (such as glass, metal, etc.). The topcoat may provide or improve barrier properties.

Topcoats may be formed from coating compositions such as, for example, polyurea coating and ethylene propylene diene monomer (“EPDM”) based polymers. In certain embodiments the topcoat comprises an anhydride/hydroxyl, melamine/hydroxyl and/or latex. In certain examples the topcoat comprises a polyepoxide and polyamine composition. In examples, the topcoat comprises a fluorine-containing polymer, such as a polyamine epoxy fluoropolymer. In certain suitable embodiments, the topcoat can be formed from Coraflon® DS-2508, PITTHANE Ultra, and/or DURANAR UC43350 extrusion coating (all of which are commercially available from PPG Industries, Inc., Pittsburgh, Pa., USA).

In certain suitable embodiments when the topcoat is used as a monocoat comprising the protective coating 110, the topcoat can be formed from coating compositions such as, for example, polyurea coating and/or EPDM based polymers. In certain embodiments, the topcoat or monocoat can be formed from Coraflon® DS-2508, PCH-90101 powder coating and/or DURANAR PD-90001 powder coating (all of which are commercially available from PPG Industries, Inc., Pittsburgh, Pa., USA).

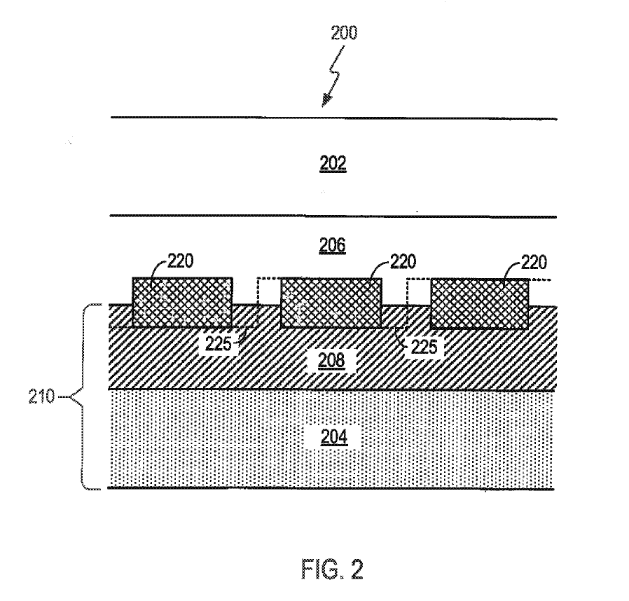

In various non-limiting embodiments, the photovoltaic modules, and all aspects thereof, as described above, can further include a primer. Shown for an example in FIG. 2, protective coating 210 of photovoltaic module 200 further comprises a primer 208 positioned in between topcoat 204 and photovoltaic cells 220, and applied or deposited on all or at least a portion of the photovoltaic cells 220, and any exposed encapsulant 206. As used herein, the term “primer” or “primer coating composition” refers to coating compositions from which an undercoating may be deposited onto a substrate in order to prepare the surface for application of a protective or decorative coating system. The primer may provide for anti-corrosion protection. In embodiments the primer can also contribute adhesion and/or barrier properties. For example, the primer may be formed from any suitable protective coating compositions.

In certain embodiments the primer may be formed from coating compositions comprising, for example, any one or more of: epoxy/amine, polyurethane, ketimine, cyclic carbonate formulations, polyaspartate coatings, anhydride/hydroxyl, melamine/hydroxyl, latex, anionic or cationic electrocoat, zinc rich primer, and/or any combination thereof. In examples, the primer can be solvent born or water borne, and in certain embodiments comprises a high solid and/or low VOC primer.

In embodiments the primer comprises a thermoset polyepoxide-polyamine composition. In certain embodiments the primer may be formed from coating compositions comprising, for example, any one or a combination of the following: DP40LF refinish primer, DURAPRIME, POWERCRON 6000, POWERCRON 150, HP-77-225 GM Primer Surfacer, SPR67868A, DURANAR UC51742 Duranar sprayable aluminum extrusion coating system, and/or Aerospace primer CA7502 (all of which are commercially available from PPG Industries, Inc., Pittsburgh, Pa., USA). In embodiments, the primer comprises DP40LF, DP48LF, CA7502, Envirobase and/or NCP (all of which are commercially available from PPG Industries, Inc., Pittsburgh, Pa., USA).

In embodiments a primer is used in combination with a topcoat comprising a polyepoxide and polyamine comprising a fluorine-containing polymer. In certain such embodiments, the primer comprises an epoxy/amine.

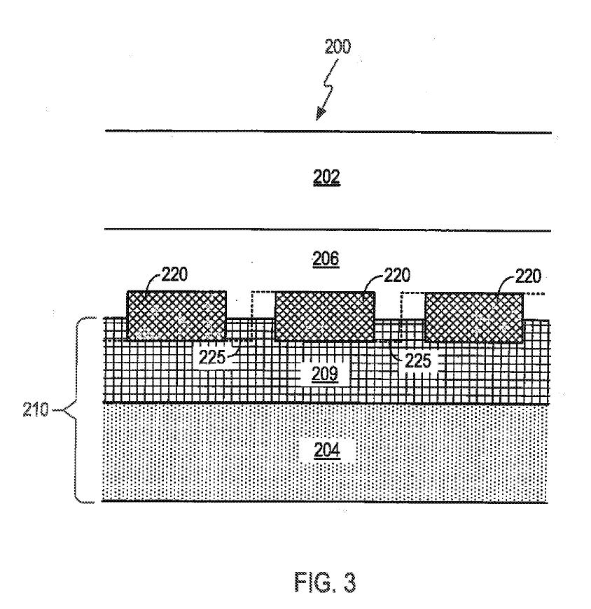

In other embodiments, shown in FIG. 3 for example, the photovoltaic module comprises a second fluid encapsulant or back encapsulant 209 positioned between the electrically interconnected photovoltaic cells 220 and the topcoat 204, and applied or deposited on all or at least a portion of the photovoltaic cells 220, and any exposed encapsulant 206. In such embodiments, for example, the topcoat comprises a polyurea and a fluorine-containing polymer. In such embodiments, for example, back encapsulant 209 comprises a coating composition comprising at least one of a polyurethane resin, a polyurea resin, or a hybrid polyurethane-polyurea resin, or a combination of such resins. In examples back encapsulant 209 comprises the same composition as the front encapsulant 206. For an example, the front and back encapsulant, 206 and 209, respectively, both comprise a liquid silicone encapsulant with a topcoat 204. They can be used, for example, with crystalline silicon cells. Optionally, a primer 208 can be used.

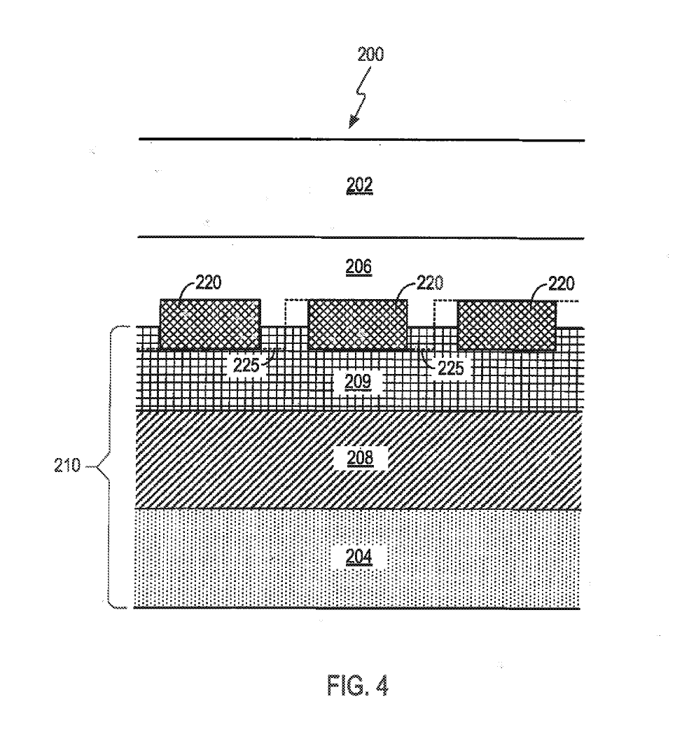

In embodiments, shown in FIG. 4 for example the photovoltaic module further comprises a primer 208 positioned between the back fluid encapsulant 209 and the topcoat 204. Any of the coatings, fluid encapsulants and/or protective coatings may comprise a UV curable coating.

The topcoat alone or in combination with a primer and/or back encapsulant and/or other coatings can comprise a protective coating system 110 or 210 that may be applied to encapsulate the photovoltaic cells and electrical interconnections between the encapsulant material and the protective coating system. In various non-limiting embodiments, the protective coating system comprises one, two, or more coats, wherein any coat or coats may individually comprise the same or a different coating composition. In various non-limiting embodiments, the coatings used to produce the one or more coats (e.g., primer, tie coat, topcoat, monocoat, and the like) comprising a protective coating system for a photovoltaic module may comprise inorganic particles in the coating composition and the resultant cured coating film. As used herein, tie coat refers to an intermediate coating intended to facilitate or enhance adhesion between an underlying coating (such as a primer or an old coating) and an overlying topcoat. For example, particulate mineral materials, such as, for example, mica, may be added to coating compositions used to produce a protective coating system 110 or 210 for photovoltaic module 100 or 200. In embodiments, the inorganic particles comprise aluminum, silica, clays, pigments and/or glass flake or any combination thereof. Inorganic particles may be added to one or more of a primer, tie coat, topcoat and/or monocoat applied on to photovoltaic cells and electrical interconnections to encapsulate these components.

Protective coating systems comprising inorganic particles in the cured coats may exhibit improved barrier properties such as, for example, lower moisture vapor transmission rates and/or lower permeance values. Inorganic particles such as, for example, mica and other mineral particulates, may improve the moisture barrier properties of polymeric films and coats by increasing the tortuosity of transport paths for water molecules contacting the films or coats. These improvements may be attributed to the relatively flat platelet-like structure of various inorganic particles. In various non-limiting embodiments, inorganic particles may comprise a platelet shape. In various non-limiting embodiments, inorganic particles may comprise a platelet shape and have an aspect ratio, defined as the ratio of the average width dimension of the particles to the average thickness dimension of the particles, ranging from 5 to 100 microns, or any sub-range subsumed therein. In embodiments the inorganic particles have an average particle size ranging from 10 to 40 microns.

In embodiments, inorganic particles, such as, for example, mica, are dispersed in the cured coating layer. In embodiments the inorganic particles are mechanically stirred and/or mixed into the coatings, or added following creation of a slurry. A surfactant may or may not be needed to assist the mixing. In embodiments inorganic particles can be mixed until fully distributed without settling. Any suitable method may be used to prepare an appropriate dispersion.

In various non-limiting embodiments, a photovoltaic module may comprise a topcoat, a monocoat, and/or a primer formed from the coating compositions described in U.S. Patent Application Publication No. 2004/0244829 to Rearick et al., which is incorporated by reference into this specification in its entirety.

The coating at the outermost backing layer of a photovoltaic module in accordance with various embodiments described in this specification may comprise inorganic particles at a loading level ranging from greater than zero to 40 percent by weight of coatings solids, or any sub-range subsumed therein, such as, for example, 8 to 12 percent or about 10 percent. A primer in between a topcoat and photovoltaic cells and electrical interconnections may comprise inorganic particles at a loading level ranging from greater than zero to 40 percent by weight of coatings solids, or any sub-range subsumed therein, such as, for example, 8 to 12 percent or about 10 percent.

A coating layer comprising the outermost backing layer or topcoat of a photovoltaic module in accordance with various embodiments described in this specification may have a maximum permeance value ranging from 0.1 to 1,000 g*mil/m²*day, or any sub—range subsumed therein, such as, for example, 1 to 500 g*mil/m²*day. A primer in between a topcoat and photovoltaic cells and electrical interconnections may have a maximum permeance value ranging from 0.1 to 1,000 g*mil/m²*day, or any sub-range subsumed therein, such as, for example, 1 to 500 g*mil/m²*day. In embodiments the permeance for the primer is less than that of the topcoat. A two- or more-layer protective coating system comprising at least a topcoat and a primer may together have a maximum permeance value ranging from 0.1 to 1,000 g*mil/m²*day, or any sub-range subsumed therein, such as, for example, 1 to 500 g*mil/m²*day. A liquid encapsulant material applied or otherwise adjacent to a front transparency may have a maximum permeance value ranging from 0.1 to 1,000 g*mil/m²*day.

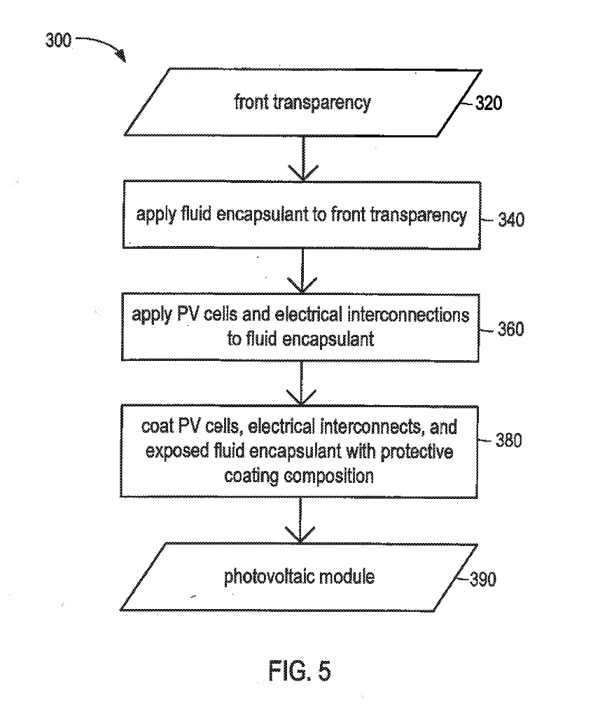

FIG. 5 illustrates a non-limiting and non-exhaustive embodiment of a process 300 for producing a photovoltaic module 390. Application of encapsulant material at 340 to the front transparency 320 may comprise depositing a transparent fluid encapsulant material, such as, for example, a clear liquid encapsulant, onto one side of the front transparency.

Photovoltaic cells and electrical interconnections may be positioned or applied onto the fluid encapsulant at 360. In various non-limiting embodiments, application of photovoltaic cells and electrical interconnections may comprise positioning bulk photovoltaic cells and electrical interconnections on the previously-applied encapsulant material and pressing the positioned bulk photovoltaic cells and electrical interconnections into the encapsulant material. Application can also include electrically connecting the cells and/or an assembly of cells. In embodiments the encapsulant material is cured to secure the bulk photovoltaic cells and electrical interconnections in place and to the front transparency. In certain embodiments, electrically-interconnected bulk photovoltaic cells may be positioned and pressed into a layer of fluid encapsulant applied to one side of a front transparency. The fluid encapsulant can be cured to solidify the composition and secure the bulk photovoltaic cells and electrical interconnections in place and to the front transparency. In embodiments photovoltaic cells are positioned but not cured until after application of a protective coating system. In various other non-limiting embodiments, application of photovoltaic cells and electrical interconnections at 360 may comprise depositing layers of a thin-film photovoltaic cell onto the encapsulant material.

A protective coating is applied or deposited on at least a portion of the photovoltaic cells at 380. In embodiments applying the protective coating comprises applying a topcoat. In embodiments the process of applying the protective coating further includes applying primer on all or a portion of the photovoltaic cells before applying the topcoat. In embodiments the process of applying the protective coating includes applying back encapsulant on all or a portion of the photovoltaic cells before applying the topcoat. In other embodiments the process of applying the protective coating includes applying back encapsulant on all or a portion of the photovoltaic cells and applying primer on all or a portion of the back encapsulant before applying the topcoat.

In various non-limiting embodiments, the one or more coats comprising a protective coating can be applied or deposited onto all or a portion of the photovoltaic cells and electrical interconnections and cured to form a coat or layer thereon (e.g., topcoat, primer coat, tie coat, clearcoat, or the like) using any suitable coating application technique in any manner known to those of ordinary skill in the art. For example, the coatings of the present invention can be applied by electrocoating, spraying, electrostatic spraying, dipping, rolling, brushing, roller coating, curtain coated, controlled dispensing, flow coating, slot die coating process, extrusion, and the like. As used herein, the phrase “deposited on” or “deposited over” or “applied” to a front transparency, photovoltaic cell, or another coating, means deposited or provided above or over but not necessarily adjacent to the surface thereof. For example, a coating can be deposited directly upon the photovoltaic cells or one or more other coatings can be applied there between. A layer of coating can be typically formed when a coating that is deposited onto a photovoltaic cell or one or more other coatings is substantially cured or dried. In addition, in embodiments, the front and/or back liquid encapsulant may be applied using any of the above-described coating application techniques.

The one or more applied coats may then form a protective coating system over all or at least a portion of a substrate and cured which, individually, as a single coat, or collectively, as more than one coat, comprise a protective barrier over at least a portion of the substrate. One such coat may be formed from a fluid encapsulant which cures to form a transparent partial or solid coat on at least a portion of a substrate (i.e., a liquid encapsulant material or clearcoat). In this regard, the term “cured,” as used herein, refers to the condition of a liquid coating composition in which a film or layer formed from the liquid coating composition is at least set-to-touch. As used herein, the terms “cure” and “curing” refer to the progression of a liquid coating composition from the liquid state to a cured state and encompass physical drying of coating compositions through solvent or carrier evaporation (e.g., thermoplastic coating compositions) and/or chemical crosslinking of components in the coating compositions (e.g., thermosetting coating compositions). In embodiments, one or more coatings can be cured by UV.

In certain embodiments, the application of a protective coat at 380 encapsulates the photovoltaic cells and electrical interconnections between the underlying fluid encapsulant and the overlying protective coat, thereby producing a photovoltaic module at 390. In various non-limiting embodiments, one or more protective coats may be applied to encapsulate the photovoltaic cells and electrical interconnections between underlying fluid encapsulant and the one or more protective coats. The topcoat may be cured to solidify the topcoat and adhere the topcoat to the underlying components and material, thereby producing a protective coat over the photovoltaic cells and electrical interconnections. In various non-limiting embodiments, the two or more coatings comprising the protective coating system may be cured sequentially or, in some embodiments, the two or more coatings comprising the protective coating system may be applied wet-on-wet and cured simultaneously. Thereafter an overlying constituent coating composition can optionally be applied.

It is understood that after applying the fluid encapsulant material 106 or 206 to one side of the front transparency 102 or 202, the one or more protective coats (for example, coats 104 or 204 and/or 208) comprising the protective coating system 110 or 210 may be applied to encapsulate the photovoltaic cells 120 or 220 and the electrical interconnections (not shown) before curing the underlying encapsulant material 106 or 206. In such embodiments, the underlying encapsulant material and the overlying coats comprising the protective coating system may be cured simultaneously to secure and adhere the photovoltaic cells and electrical interconnections (not shown) to the front transparency. In addition, the photovoltaic cells and electrical interconnections (not shown) may be encapsulated between the fluid encapsulant and the overlying coats comprising the protective coating system. In this manner, the fluid encapsulant, the optional primer and/or back encapsulant, and the topcoat may be applied wet-on-wet and then cured simultaneously. Alternatively, the coats 206, 208 and/or 209, and 204, for example, may be partially or fully cured sequentially before application of an overlying constituent coat or, in some embodiments, the fluid encapsulant may be partially or fully cured before application of the protective coating system, and topcoat may be applied wet-on-wet to primer and the protective coating system may be cured simultaneously.

In embodiments the topcoat or a monocoat comprises a dry (cured) film thickness ranging from 0.2 to 25 mils, or any sub-range subsumed therein, such as, for example, 1 to 10 mils, or 5 to 8 mils A primer in between a topcoat and photovoltaic cells, electrical interconnects, and exposed encapsulant material may have a dry (cured) film thickness ranging from 0.2 to 10 mils, or any sub-range subsumed therein, such as, for example, 1 to 2 mils A two- or more-layer protective coating system comprising at least a topcoat and a primer may together have a dry (cured) film thickness ranging from 0.5 to 25 mils, or any sub-range subsumed therein, such as, for example, 1 to 10 mils, or 5 to 8 mils A liquid encapsulant material applied to a front transparency may have a dry (cured) film thickness ranging from 0.2 to 25 mils, or any sub-range subsumed therein, such as, for example, 5 to 15 mils, or 8 to 10 mils.

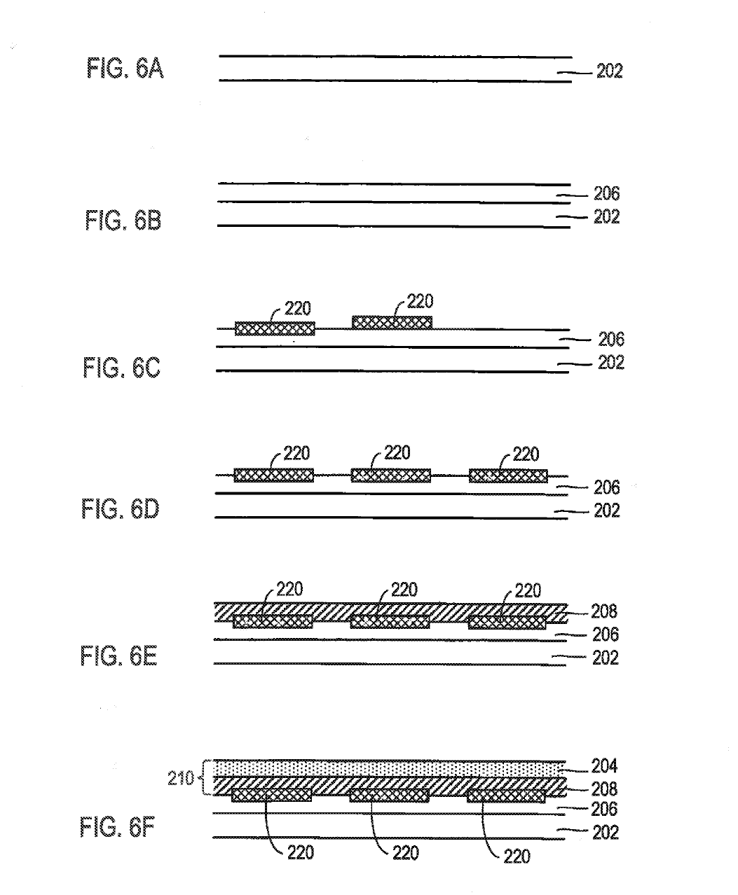

FIGS. 6A through 6F schematically illustrate the production of a photovoltaic module comprising the application of a two-coat protective coating system comprising a primer and a topcoat. A front transparency 202 (e.g., a glass or polyimide sheet) is provided in FIG. 6A. FIG. 6B shows an encapsulant material 206 (e.g., a positioned EVA sheet or a spray-coated fluid encapsulant) applied onto one side of the front transparency 202. In FIG. 6C, photovoltaic cells 220 (e.g., comprising crystalline silicon wafers) are shown being applied onto the encapsulant material 206 (electrical interconnections are not shown for clarity). The photovoltaic cells 220 (and electrical interconnections, not shown) may be positioned on the encapsulant material 206 and may be pressed into the encapsulant material 206. The encapsulant material 206 may be cured to secure the assembly of photovoltaic cells 220 (and electrical interconnections, not shown) in place and to the front transparency 202, as shown in FIG. 6D. FIG. 6E shows a primer 208 applied onto and coating the photovoltaic cells 220 and electrical interconnections (not shown). FIG. 6F shows a topcoat 204 applied onto the primer 208, in which the topcoat 204 and the primer 208 together comprise a protective coating system 210.

Various non-limiting embodiments described in this specification may address certain disadvantages of the vacuum lamination processes in the production of photovoltaic modules. For example, it will be appreciated that the processes described in this specification may eliminate the lamination of preformed backsheets and back side encapsulant material sheets to photovoltaic cells and front transparencies. In embodiments of the present disclosure, the preformed backsheets and back side encapsulant materials may be replaced with protective coating systems comprising one or more applied coatings that provide comparable or superior encapsulation of the photovoltaic cells and electrical interconnections. In addition, the protective coating systems described in the present disclosure may provide one or more advantages to photovoltaic modules, such as good durability, moisture barrier, abrasion resistance, and the like. In embodiments of the present disclosure, traditional encapsulant material, such as EVA film, can be replaced with fluid encapsulant. In embodiments, traditional encapsulant material can be replaced with fluid encapsulant, and the backsheets and back side encapsulant materials may be replaced with protective coating systems comprising one or more applied coatings that provide comparable or superior encapsulation of the photovoltaic cells and electrical interconnections. In embodiments replacement of traditional encapsulant material can eliminate the need for vacuum lamination.

Various embodiments are described and illustrated in this specification to provide an overall understanding of the structure, function, properties, and use of the disclosed modules and processes. It is understood that the various embodiments described and illustrated in this specification are non-limiting and non-exhaustive. Thus, the invention is not limited by the description of the various non-limiting and non-exhaustive embodiments disclosed in this specification. The features and characteristics described in connection with various embodiments may be combined with the features and characteristics of other embodiments. Such modifications and variations are intended to be included within the scope of this specification. As such, the claims may be amended to recite any features or characteristics expressly or inherently described in, or otherwise expressly or inherently supported by, this specification. Further, Applicants reserve the right to amend the claims to affirmatively disclaim features or characteristics that may be present in the prior art. Therefore, any such amendments comply with written description support requirements. The various embodiments disclosed and described in this specification can comprise, consist of, or consist essentially of the features and characteristics as variously described herein.

In this specification, other than where otherwise indicated, all numerical parameters are to be understood as being prefaced and modified in all instances by the term “about”, in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described in this specification should at least be construed in light of the number of reported significant digits and by applying ordinary rounding techniques.

Also, any numerical range recited in this specification is intended to include all sub-ranges of the same numerical precision subsumed within the recited range. For example, a range of “1.0 to 10.0” is intended to include all sub-ranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited in this specification is intended to include all lower numerical limitations subsumed therein and any minimum numerical limitation recited in this specification is intended to include all higher numerical limitations subsumed therein. Accordingly, Applicants reserve the right to amend this specification, including the claims, to expressly recite any sub-range subsumed within the ranges expressly recited herein. All such ranges are intended to be inherently described in this specification such that amending to expressly recite any such sub-ranges would comply with written description support requirements.

The grammatical articles “one”, “a”, “an”, and “the”, as used in this specification, are intended to include “at least one” or “one or more”, unless otherwise indicated. Thus, the articles are used in this specification to refer to one or more than one (i.e., to “at least one”) of the grammatical objects of the article. By way of example, “a photovoltaic cell” means one or more photovoltaic cells, and thus, possibly, more than one photovoltaic cell is contemplated and may be employed or used in an implementation of the described embodiments. Further, the use of a singular noun includes the plural, and the use of a plural noun includes the singular, unless the context of the usage requires otherwise.

It should be understood that in certain embodiments described herein certain components and/or coats may be referred to as being “adjacent” to one another. In this regard, it is contemplated that adjacent is used as a relative term and to describe the relative positioning of layers, coats, photovoltaic cells, and the like comprising a photovoltaic module. It is contemplated that one coat or component may be either directly positioned or indirectly positioned beside another adjacent component or coat. In embodiments where one component or coat is indirectly positioned beside another component or coat, it is contemplated that additional intervening layers, coats, photovoltaic cells, and the like may be positioned in between adjacent components. Accordingly, and by way of example, where a first coat is said to be positioned adjacent to a second coat, it is contemplated that the first coat may be, but is not necessarily, directly beside and adhered to the second coat.

Any patent, publication, or other disclosure material identified herein is incorporated by reference into this specification in its entirety unless otherwise indicated, but only to the extent that the incorporated material does not conflict with existing definitions, statements, or other disclosure material expressly set forth in this specification. As such, and to the extent necessary, the express disclosure as set forth in this specification supersedes any conflicting material incorporated by reference herein. Any material, or portion thereof, that is said to be incorporated by reference into this specification, but which conflicts with existing definitions, statements, or other disclosure material set forth herein, is only incorporated to the extent that no conflict arises between that incorporated material and the existing disclosure material. Applicant(s) reserve the right to amend this specification to expressly recite any subject matter, or portion thereof, incorporated by reference herein.

The non-limiting and non-exhaustive examples that follow are intended to further describe various non-limiting and non-exhaustive embodiments without restricting the scope of the embodiments described in this specification.

### EXAMPLES

### Example-1

Photovoltaic modules comprising a protective coating system comprising photovoltaic cells and electrical interconnects having a front transparency and an encapsulant on one side and a protective coating system (comprising one of a topcoat; a topcoat and primer; a topcoat and back encapsulant; or a topcoat, primer and backcoat encapsulant) were evaluated under International standard IEC 61215, second edition, 2005, “Crystalline silicon terrestrial photovoltaic (PV) modules—Design qualification and type approval.” The photovoltaic modules comprising the protective coating system were compared to photovoltaic modules comprising an EVA copolymer back encapsulant material and a TPT backsheet. The control tested photovoltaic modules were obtained from Spire Corporation (Bedford, Mass., USA), Solar Power Industries (SPI) and Everbright Solar and comprised crystalline silicon photovoltaic cells and electrical interconnects (tabs and bus-bars) adhered to glass front transparencies with a sheet of laminated EVA copolymer front potting encapsulant material.

The primary control modules were produced by vacuum laminating crystalline silicon solar cells in between a glass front transparency, a single sheet of EVA copolymer front encapsulant material, a single sheet of EVA copolymer back encapsulant material, and a polyvinyl fluoride backsheet, thereby encapsulating the crystalline silicon photovoltaic cells and electrical interconnects in EVA copolymer sandwiched between the glass and the backsheet. The experimental modules were produced at PPG Industries, Inc. by depositing a layer of fluid encapsulant on PV glass, laying down soldered crystalline silicon photovoltaic cells and electrical interconnects and minimizing air bubbles entrapment, (optionally, depositing another layer of fluid encapsulant and/or a primer coat), then spray coating and curing a topcoat.

a. Visual Inspection—Test Procedure IEC 61215-10.1

Each experimental and control photovoltaic (i.e., test) module was inspected for visual defects as described in IEC 61215-10.1.2. No cracked or broken cells were observed. The surfaces of the test modules were not tacky and no bonding or adhesion failures were found at encapsulant material or coating interfaces. There was no delamination or bubbles. No faulty interconnections or electrical termination were found. In general, there were no observable conditions that would be expected to negatively affect performance.

b. Maximum Power Determination—Test Procedure IEC 61215-10.2

The maximum power (Pₘ) and the fill factor (FF) for each test module was measured using a solar simulator according to the standard procedures described in IEC 61215-10.2.3 and using simulated solar irradiance of 1 sun. Each test module was measured before and after durability testing. Pₘ and FF were also measured at various time intervals during each test to monitor the performance progression.

c. Insulation Test—Test Procedure IEC 61215-10.3

Dry current leakage was determined for each test module according to the standard test procedures described in IEC 61215-10.3.4. Since the test modules contained only one photovoltaic cell and had a maximum system voltage that did not exceed 50 V, an applied voltage of 500 V was used for this test as described in IEC 61215-10.3.3c. All of the test modules passed the test requirements specified in IEC 61215-10.3.5, i.e., insulation resistance not exceeding 400 MΩ, and 40 MΩ per m². This insulation test was performed before and after durability testing and at various time intervals during durability testing to monitor performance progression.

d. Damp Heat Test—Test Procedure IEC 61215-10.13

Durability to high temperature and high humidity exposure was determined by subjecting the test modules to the damp heat test procedure described in IEC 61215-10.13.2. The test modules were exposed to 85° C. and 85% relative humidity for a period of 1000 hours. Test modules were withdrawn from the damp heat chamber for evaluation at time intervals of 500 hours to evaluate how module performance was affected over time throughout the duration of the test. The withdrawn modules were then returned to the damp heat chamber to continue exposure. Each of the test modules was tested in triplicate.

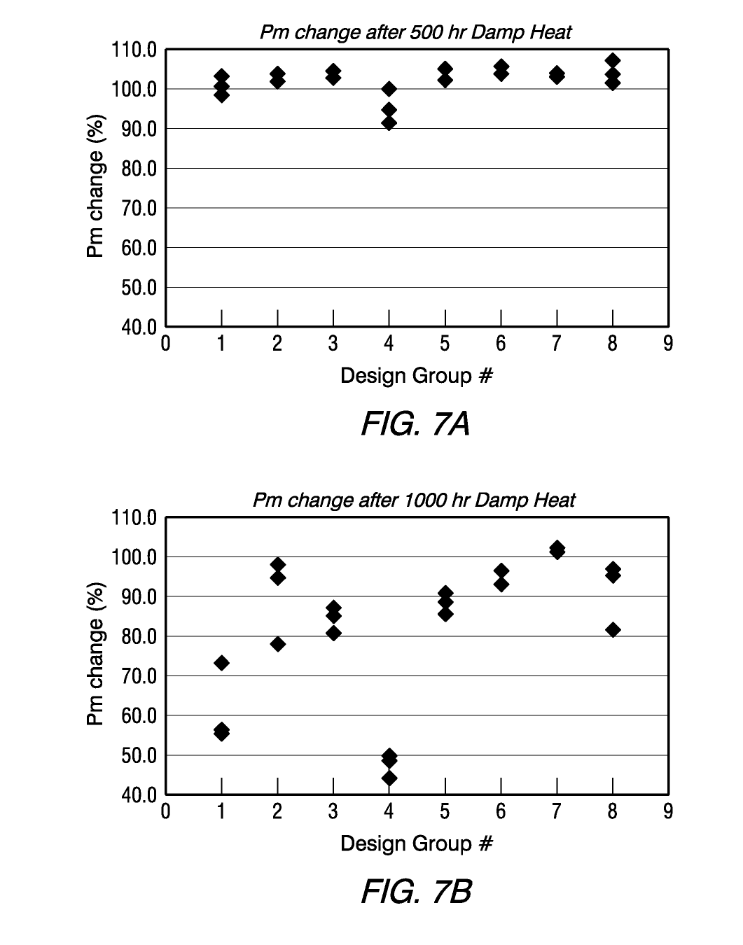

The results of the testing are reported in Table 1 and shown in FIGS. 7A and 7B.

TABLE 1¹
P_{M} (mW)

| | | | | | % change of | | % change of |
|---|---|---|---|---|---|---|---|
| | | | | Pm after | Pm after | Pm after | Pm after |
| | | | Initial | 500 hr | 500 hr | 1000 hr | 1000 hr |
| Design | group # | ID | Pm | DH | DH | DH | DH |
| A: PPG | 1 | 12-027 | 1627.67 | 1638.93 | 98.2 | 925.4 | 55.5 |
| Encapsulant/ | 1 | 12-029 | 1641.12 | 1719.79 | 103.0 | 1216.1 | 72.8 |
| primer/topcoat A | 1 | 12-030 | 1619.7 | 1675.55 | 100.5 | 940.1 | 56.4 |
| B: PPG Encapsulant/ | 2 | 12-009 | 1628.2 | 1711.57 | 101.8 | 1302.8 | 77.5 |
| PPG Encapsulant/ | 2 | 12-010 | 1638.83 | 1714.3 | 102.3 | 1633.5 | 97.4 |
| primer/topcoat A | 2 | 12-031 | 1633.25 | 1708.28 | 103.6 | 1559.3 | 94.6 |
| C: PPG Encapsulant/ | 3 | 12-036 | 1622.61 | 1705.28 | 104.4 | 1413.7 | 86.5 |
| PPG Encapsulant/ | 3 | 12-038 | 1619.17 | 1690.45 | 103.1 | 1389.3 | 84.8 |
| topcoat A | 3 | 12-039 | 1647.3 | 1729.3 | 102.9 | 1353.3 | 80.5 |
| D: PPG | 4 | 12-045 | 1633.41 | 1673.40 | 100.0 | 830.7 | 49.7 |
| Encapsulant/ | 4 | 12-046 | 1612.09 | 1570.94 | 94.6 | 724.0 | 43.6 |
| primer/topcoat B | 4 | 12-053 | 1608.95 | 1534.63 | 91.3 | 814.0 | 48.4 |
| E: PPG Encapsulant/ | 5 | 12-050 | 1621.38 | 1729.83 | 104.5 | 1461.3 | 88.2 |
| PPG Encapsulant/ | 5 | 12-051 | 1608.28 | 1727.87 | 105.0 | 1489.0 | 90.5 |
| primer/topcoat B | 5 | 12-052 | 1621.92 | 1696.86 | 102.3 | 1412.5 | 85.2 |
| F: PPG Encapsulant/ | 6 | 12-057 | 1557.47 | 1648.53 | 104.1 | 1524.8 | 96.2 |
| PPG Encapsulant/ | 6 | 12-058 | 1568.26 | 1666.62 | 105.7 | 1512.5 | 95.9 |
| topcoat B | 6 | 12-059 | 1579.54 | 1666.78 | 103.5 | 1491.1 | 92.6 |
| G: control, | 7 | 12-077 | 1642.99 | 1720.01 | 103.1 | 1678.5 | 100.6 |
| EVA/TPT | 7 | 12-079 | 1647.4 | 1741.90 | 103.5 | 1703.5 | 101.2 |
| topsheet | 7 | 12-080 | 1612.4 | 1696.88 | 103.1 | 1675.1 | 101.7 |
| H: PPG | 8 | 12-085 | 1617.99 | 1645.43 | 101.7 | 1539.6 | 95.2 |
| Encapsulant/ | 8 | 12-086 | 1605.11 | 1719.83 | 107.1 | 1547.7 | 96.4 |
| topcoat B | 8 | 12-090 | 1610.09 | 1669.16 | 103.7 | 1310.4 | 81.4 |

In general, all test modules showed about 1600 mW of power at Pₘ. Experimental coated test modules showed approximately the same Pₘ output as the control EVA/backsheet laminated test modules (Table 1). Similar results were observed for fill factor measurements.

The control EVA/backsheet laminated test modules showed less than a 5% loss in maximum power output over the entire 1000 hour duration of the damp heat test. Similar results were observed for fill factor measurements. Experimental coated test modules exhibited stable maximum power output after 500 exposure hours in the damp heat test. Group 4 showed some degradation. After 1000 hours exposure, Groups 2, 6 and 8 performed best among these designs and close to control. Group 4 showed the least performance and almost lost 50% of the original Pm.

e. Thermal Cycling Test—Test Procedure IEC 61215-10.11

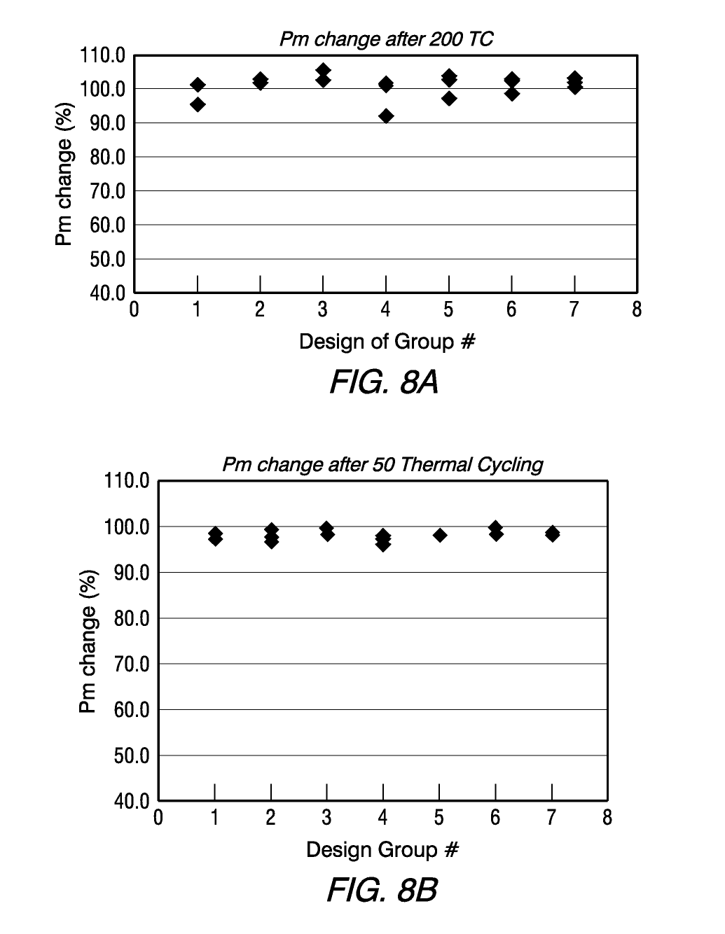

The durability of the test modules to thermal cycling between −40° C. and 85° C. was evaluated by subjecting the test modules to the thermal cycling test procedure described in IEC 61215-10.11.3 (without current). The thermal cycling was repeated for 200 cycles. Test modules were analyzed after all 200 cycles were completed; no analysis was performed at intermediate cycling intervals. Each of the test modules was tested in triplicate. The results of the testing are reported in Table 2 and FIGS. 8A and 8B.

TABLE 2
P_{M} (mW)

| | | | | Pm | Pm change |
|---|---|---|---|---|---|
| | | | | after | after 200 TC |
| Design | group # | ID | Initial Pm | 200 TC | (%) |
| A: PPG | 1 | 12-023 | 1668.43 | 1591.3 | 95.4 |
| Encapsulant/ | 1 | 12-013 | 1670 | 1684.1 | 100.8 |
| primer/topcoat A | 1 | 12-025 | 1666.57 | 1684.8 | 101.1 |
| B: PPG | 2 | 12-006 | 1680.75 | 1700.3 | 101.2 |
| Encapsulant/PPG | 2 | 12-007 | 1676.54 | 1710.9 | 102.1 |
| Encapsulant/ | 2 | 12-008 | 1648.9 | 1687.0 | 102.3 |
| primer/topcoat A | | | | | |
| C: PPG | 3 | 12-033 | 1633.65 | 1715.2 | 105.0 |
| Encapsulant/PPG | 3 | 12-034 | 1639.27 | 1727.7 | 105.4 |
| Encapsulant/ | 3 | 12-035 | 1680.62 | 1715.5 | 102.1 |
| topcoat A | | | | | |
| D: PPG | 4 | 12-040 | 1673.03 | 1678.2 | 100.3 |
| Encapsulant/ | 4 | 12-041 | 1660.07 | 1682.8 | 101.4 |
| primer/topcoat B | 4 | 12-044 | 1680.33 | 1545.1 | 92.0 |
| E: PPG | 5 | 12-043 | 1656.07 | 1701.1 | 102.7 |
| Encapsulant/PPG | 5 | 12-047 | 1645.22 | 1599.8 | 97.2 |
| Encapsulant/ | 5 | 12-049 | 1658.42 | 1719.0 | 103.7 |
| primer/topcoat B | | | | | |
| F: PPG | 6 | 12-054 | 1584.27 | 1618.0 | 102.1 |
| Encapsulant/PPG | 6 | 12-055 | 1576.7 | 1619.1 | 102.7 |
| Encapsulant/ | 6 | 12-056 | 1610.42 | 1587.2 | 98.6 |
| topcoat B | | | | | |
| G: control, | 7 | 12-070 | 1667.88 | 1694.39 | 101.6 |
| EVA/TPT | 7 | 12-071 | 1682.46 | 1694.98 | 100.7 |
| backsheet | 7 | 12-075 | 1646.37 | 1696.57 | 103.0 |
| H: PPG | 8 | | 1617.99 | | 0.0 |
| Encapsulant/ | 8 | | 1605.11 | | 0.0 |
| topcoat B | 8 | | 1610.09 | | 0.0 |

The control laminated test modules showed good durability in the thermal cycling test. The mean output power from the three control test modules decreased by less than 5% after 50 and 200 thermal cycles. Similarly, a majority of the experimental coated test modules showed less than 5% reduction in mean output power after 50 and 200 thermal cycles.

f. Humidity Freeze Test—Test Procedure IEC 61215-10.12

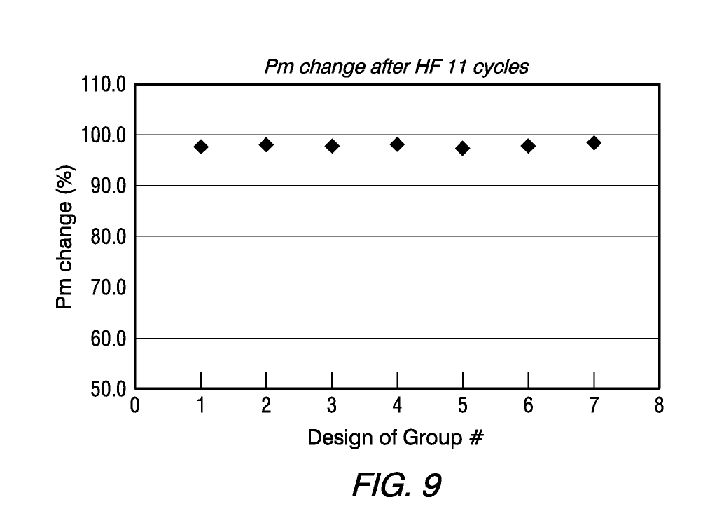

The durability of the test modules to thermal cycling between −40° C. and 85° C. with 85% relative humidity was evaluated by subjecting the test modules to the thermal cycling test procedure described in IEC 61215-10.12.3 (without current). The thermal cycling was repeated for 11 cycles. Test modules were analyzed after all 11 cycles were completed; no analysis was performed at intermediate cycling intervals. The results of the testing are reported in Table 3 and FIG. 9.

TABLE 3
P_{M} (mW)

| | | | | | Pm |
|---|---|---|---|---|---|
| | | | | Pm | change |
| | group | | Initial | after 11 | after 11 |
| Design | # | ID | Pm | HF | HF (%) |
| A: PPG Encapsulant/ | 1 | 12-025 | 1619.50 | 1580.183 | 97.6 |
| primer/topcoat A | | | | | |
| B: PPG Encapsulant/PPG | 2 | 12-008 | 1641.90 | 1610.95 | 98.1 |
| Encapsulant/ | | | | | |
| primer/topcoat A | | | | | |
| C: PPG Encapsulant/PPG | 3 | 12-034 | 1657.09 | 1619.78 | 97.7 |
| Encapsulant/topcoat A | | | | | |
| D: PPG Encapsulant/ | 4 | 12-041 | 1646.15 | 1616.207 | 98.2 |
| primer/topcoat B | | | | | |
| E: PPG Encapsulant/PPG | 5 | 12-049 | 1669.97 | 1625.383 | 97.3 |
| Encapsulant/primer/ | | | | | |
| topcoat B | | | | | |
| F: PPG Encapsulant/PPG | 6 | 12-054 | 1582.17 | 1547.517 | 97.8 |
| Encapsulant/topcoat B | | | | | |
| G: control, EVA/TPT | 7 | 12-071 | 1644.20 | 1621.607 | 98.6 |
| backsheet | | | | | |
| PPG Encapsulant A/PPG | | 12-152 | 1672.84 | crack | |
| Topcoat B | | | | | |
| PPG Encapsulant B/PPG | | 12-161 | 1672.82 | crack | |
| Topcoat B | | | | | |

¹In Tables 1-3, Encapsulant, Encapsulant A and Encapsulant B comprise three different polyurethane resins. Primer is Primer 1 in Table 4. Topcoats A and B are identified in Table 4.

All testing modules have less than 5% drop on Pm after this exposure, similar to the control group.

### Example-2

The moisture barrier properties of three primer coating compositions, two top coating compositions; and various encapsulant compositions were measured and compared against the moisture barrier properties of EVA copolymer encapsulant material films and polyvinyl fluoride backsheets. The tested materials are listed in Table 4. The as-received EVA copolymer film had a measured permeance of 458 g*mil/m²*day, and EVA copolymer material that had undergone a vacuum lamination process had a measured permeance of 399 g*mil/m²*day. The as-received Tedlar® backsheet material had a measured permeance of 30 g*mil/m²*day. The coating compositions were cast and cured to form freestanding films (single-layer films or two-layer films).

TABLE 4
Tested Materials

| | | | Permeance |
|---|---|---|---|
| Material | Description | Supplier | (g * mil/m² * day) |
| EVA co-polymer | encapsulant material | Spire, Massachusetts, | 300-500 |
| | film | USA | |
| Tedlar ® | polyvinyl fluoride | E. I. du Pont de | 30-35 |
| | backsheet material | Nemours and | |
| | | Company, | |
| | | Wilmington, | |
| | | Delaware, USA | |
| PPG Primer 1 | epoxy primer coating | PPG Industries, Inc., | 40-45 |
| | | Pittsburgh, | |
| | | Pennsylvania, USA | |
| PPG Primer 2 | epoxy primer coating | PRC-DeSoto | 20-29 |
| | | International, Inc., | |
| | | Sylmar, California, | |
| | | USA | |
| PPG Primer 3 | epoxy primer coating | PRC-DeSoto | 20-29 |
| | | International, Inc., | |
| | | Sylmar, California, | |
| | | USA | |
| PPG Topcoat A | polyamide epoxy | PPG Industries, Inc., | 45-90 |
| | fluoropolymer top | Pittsburgh, | |
| | coating | Pennsylvania, USA | |
| PPG Topcoat B | polyurea coating | PPG Industries, Inc., | 500-800 |
| | | Pittsburgh, | |
| | | Pennsylvania, USA | |
| PPG Encapsulant 1 | Polyurethane coating | PPG Industries, Inc., | 400-450 |
| (Example 5a) | | Pittsburgh, | |
| | | Pennsylvania, USA | |
| PPG Encapsulant 2 | Polyurethane coating | PPG Industries, Inc., | 550-650 |
| (Example 5b) | | Pittsburgh, | |
| | | Pennsylvania, USA | |
| PPG Encapsulant 3 | Polyurethane coating | PPG Industries, Inc., | 800-900 |
| (Example 5c) | | Pittsburgh, | |
| | | Pennsylvania, USA | |
| PPG Encapsulan 4 | Polyurethane coating | PPG Industries, Inc., | 150-200 |
| | | Pittsburgh, | |
| | | Pennsylvania, USA | |
| PPG Encapsulant 5 | Polyurethane coating | PPG Industries, Inc., | 100-150 |
| | | Pittsburgh, | |
| | | Pennsylvania, USA | |

Lower permeance values can be achieved using higher cure temperatures. This is consistent with the concept that higher crosslink density is achieved at higher cure temperatures, and that higher crosslink density increases film resistance to moisture permeation.

### Example-3

The moisture barrier properties of two primer coating compositions, one top coating composition; and a two-layer system of a primer coating and a top coating composition were measured with and without the addition of mica at various loading levels. The tested materials are listed in Table 5. The coating compositions (with and without mica additions) were cast and cured to form freestanding films (single-layer films or two-layer films) and the moisture vapor transmission rates and permeance values of the films were measured. Two types of mica were utilized: as-received and after surface treatment with a coupling agent. (The coating/surface treatment was performed by a third party, Aculon, Inc.).

The results for the various cast coating films are reported in Table 6.

TABLE 5
Tested Materials

| Material | Description | Supplier |
|---|---|---|
| DP40LF | epoxy primer coating | PPG Industries, Inc., Pittsburgh, |
| | | Pennsylvania, USA |
| CA7502 | epoxy primer coating | PRC-DeSoto International, Inc., |
| | | Sylmar, California, USA |
| Coraflon ® | polyamide epoxy | PPG Industries, Inc., Pittsburgh, |
| DS-2508 | fluoropolymer | Pennsylvania, USA |
| | top coating | |
| Sun Mica | particulate mica | Sun Chemical, USA |

TABLE 6
Permeance (g * mil/m² * day)

Mica level
(weight percent in
coating solids)

| Coating Film | Mica | 0% | 10% |
|---|---|---|---|
| DP40LF mono-layer | Untreated | 27 | 23 |
| DP40LF mono-layer | Treated | 27 | 19 |
| CA7502 mono-layer | Untreated | 14 | 10 |
| CA7502 mono-layer | Treated | 14 | 12 |
| Coraflon mono-layer | Untreated | 52 | 53 |
| Coraflon mono-layer | Treated | 52 | 28 |
| DP40LF/Coraflon two-layer | Untreated | 29 | 22 |
| DP40LF/Coraflon two-layer | Treated | 29 | 21 |

TABLE 7
Permeance (g * mil/m² * day)

| | | Mica level (weight | | | |
|---|---|---|---|---|---|
| | | percent in coating solids) | | | |
| Coating Film | Mica | 0% | 10% | 15% | 20% |
| Coraflon mono-layer | Untreated | 52 | 53 | 34 | 25 |
| Coraflon mono-layer | Treated | 52 | 28 | 25 | 26 |
| DP40LF/Coraflon two-layer | Untreated | 29 | 22 | 23 | 23 |
| DP40LF/Coraflon two-layer | Treated | 29 | 21 | 28 | 17 |

The effectiveness of both treated and untreated mica as an additive was evaluated in both topcoats and primer coats. Mica loading in Coraflon® freestanding films was varied from 0 to 20 weight percent (Table 6). Results show that adding mica can reduce permeance by as much as 50% at higher loading levels. Surface-treated mica appears to decrease permeance by 45% at 10 wt % loading based on coating solids, while untreated mica required 20 wt % loading to achieve similar moisture vapor barrier performance. The moisture vapor permeance of a DP40LF/Coraflon® two-layer film without added mica equaled the best results for a Coraflon® mono-layer film with added mica. The addition of mica to Coraflon® in the primer/topcoat system reduced permeance by about 25%. The addition of 20 wt % treated mica resulted in permeance values for the primer/topcoat system that were nearly half the permeance values of Tedlar® backsheets, i.e., 17 g*mil/m²*day compared to 30 g*mil/m²*day.

The benefit of adding mica to primer coats is somewhat different than that observed with Coraflon® topcoats. For DP40LF primer coat, adding 10% untreated mica by weight of coating solids content reduced permeance by 15% (Table 5). The addition of treated mica to DP40LF primer coat reduced permeance by over 30%. The addition of 10 weight percent untreated mica produced a 32% reduction in moisture vapor permeance for CA7502 primer film. The addition of 10 weight percent treated mica reduced the permeance of CA7502 primer film by 18%.

These results show that the addition of inorganic particulate materials, such as, for example, mica, to coating compositions produces protective coating systems that provide improved barrier properties for photovoltaic module encapsulation.

Resins for use in making the fluid encapsulants were synthesized as described in Examples 4a-4d. Examples 4a, 4b and 4c are polyester polyol resins used for making polyurethane encapsulants when combined with the isocyanate-functional resin prepared in Example 4d. Example 4d is also used to make a polyurea encapsulant when combined with the amines described in Example 6a.

### Example 4a

A polyester polyol resin was prepared from the ingredients identified in Table 8 and as described below:

TABLE 8
Polyester Polyol Resin

| Ingredients | Parts by Weight (grams) |
|---|---|
| 1,6-Hexanediol | 236 |
| 2-Methyl-1,3-propanediol | 180 |
| Trimethylol propane | 143 |
| Adipic acid | 584 |
| Butylstannoic acid | 1.14 |
| Triphenyl phosphite | 0.57 |

A total of 236 grams of 1,6-hexanediol, 180 grams of 2-methyl-1,3-propanediol, 143 grams of trimethylol propane, 584 grams of adipic acid, 1.14 grams of butylstannoic acid and 0.57 grams of triphenyl phosphite were added to a suitable reaction vessel equipped with a stirrer, temperature probe, a steam heated reflux condenser with a distillation head. The reactor was equipped with an inlet used to flush the reactor with a flow of nitrogen. The contents of the flask were heated to 93° C. and continued heating to 164° C. The nitrogen cap was switched to a nitrogen sparge. At this time, water began to be evolved from the reaction. The temperature of the reaction mixture was raised to 193° C. and then to 216° C. and finally to 221° C. and held at that temperature until 142 grams of water had been distilled and the acid value of the reaction mixture was found to be 4.7. The contents of the reactor were cooled and poured out. The final material was a viscous liquid material with a measured solids of 98%, a hydroxyl value of 177 and a weight average molecular weight of 4,375 as measured against a polystyrene standard.

### Example 4b

A polyester was prepared from the following ingredients as described below:

TABLE 9
Polyester Polyol Resin

| Ingredients | Parts by Weight (grams) |
|---|---|
| 1,6-Hexanediol | 177 |
| 2-Methyl-1,3-propanediol | 135 |
| Trimethylol propane | 215 |
| Adipic acid | 438 |
| Butylstannoic acid | 0.96 |
| Triphenyl phosphite | 0.48 |

A total of 177 grams of 1,6-hexanediol, 135 grams of 2-methyl-1,3-propanediol, 215 grams of trimethylol propane, 438 grams of adipic acid, 0.96 grams of butylstannoic acid and 0.48 grams of triphenyl phosphite were added to a suitable reaction vessel equipped with a stirrer, temperature probe, a steam heated reflux condenser with a distillation head. The reactor was equipped with an inlet used to flush the reactor with a flow of nitrogen. The contents of the flask were heated to 93° C. and continued heating to 141° C. The nitrogen cap was switched to a nitrogen sparge. The reaction mixture was then heated to 164° C. At this time, water began to be evolved from the reaction. The temperature of the reaction mixture was raised to 197° C. and finally to 222° C. and held at that temperature until 106 grams of water had been distilled and the acid value of the reaction mixture was found to be 1.3. The contents of the reactor were cooled and poured out. The final material was a viscous liquid material with a measured solids of 94%, a hydroxyl value of 303 and a weight average molecular weight of 2,291 as measured against a polystyrene standard.

### Example 4c

A polyester was prepared from the following ingredients as described below:

TABLE 10
Polyester Polyol Resin

| Ingredients | Parts by Weight (grams) |
|---|---|
| 1,6-Hexanediol | 177 |
| 2-Methyl-1,3-propanediol | 135 |
| Trimethylol propane | 161 |
| Adipic acid | 438 |
| Butylstannoic acid | 0.91 |
| Triphenyl phosphite | 0.46 |

A total of 177 grams of 1,6-hexanediol, 135 grams of 2-methyl-1,3-propanediol, 161 grams of trimethylol propane, 438 grams of adipic acid, 0.91 grams of butylstannoic acid and 0.46 grams of triphenyl phosphite were added to a suitable reaction vessel equipped with a stirrer, temperature probe, a steam heated reflux condenser with a distillation head. The reactor was equipped with an inlet used to flush the reactor with a flow of nitrogen. The contents of the flask were heated to 93° C. and continued heating to 164° C. The nitrogen cap was switched to a nitrogen sparge. At this time, water began to be evolved from the reaction. The temperature of the reaction mixture was raised to 184° C. and finally to 221° C. and held at that temperature until 103 grams of water had been distilled and the acid value of the reaction mixture was found to be 0.8. The contents of the reactor were cooled and poured out. The final material was a viscous liquid material with a measured solids of 96%, a hydroxyl value of 249 and a weight average molecular weight of 2,863 as measured against a polystyrene standard.

### Example 4d

A polyisocyanate resin was prepared from the following ingredients as described below:

TABLE 11
Polyisocyanate Resin

| Ingredients | Parts by Weight (grams) |
|---|---|
| Isophorone diisocyanate | 484 |
| Terathane 650 | 682 |
| Dibutyltin dilaurate | 0.076 |
| Desmodur XP2580 | 880 |
| Desmodur XP2410 | 879 |

A total of 484 grams of isophorone diisocyanate was added to a suitable reaction vessel equipped with a stirrer, temperature probe and a reflux condenser. The reactor was equipped with an inlet used to flush the reactor with a flow of nitrogen. A total of 682 grams of Terathane 650 was added to the reactor and the contents mixed thoroughly. A total of 0.08 grams of dibutyltin dilaurate was added to the reactor and the contents were stirred for 15 minutes. The contents of the flask were then heated slowly to 52° C. and then to 86° C. The contents of the reactor began to exotherm and continued heating to 122° C. When the exotherm subsided, the isocyanate equivalent weight of the contents were measured and found to be 519. The contents of the reactor were then cooled to 80° C. A total of 880 grams of Desmodur XP2580 and 879 grams of Desmodur XP2410 were added to the reactor and the contents mixed for 15 minutes. The final material was a liquid resin with a measured solids of 97%, an isocyanate equivalent weight of 259 grams/equivalent and a weight average molecular weight of 1876 as measured against a polystyrene standard.

### Example—5a-5c

Polyurethane fluid encapsulant formulations were prepared using the resins of Example 4 as follows.

TABLE 12
Polyurethane Fluid Encapsulant

| | Example 5a | Example 5b | Example 5c |
|---|---|---|---|
| Components | | | |
| Polyol | 69.20 Ex. 4a | 78.65 Ex. 4b | 90.35 Ex. 4c |
| Isocyanate | 120.64 Ex. 4d | 121.13 Ex. 4d | 109.44 Ex. 4d |
| Catalyst | .11 DBTDL | .17 DBTDL | .15 DBTDL |
| Additive | 9.94 TMP | | |
| Ratio (NCO/OH) | 1.07 | 1.08 | 1.06 |
| Paint Properties | | | |
| Gel Point (time h:mm:ss) | 1:21:10 | 1:01:35 | 1:05:59 |
| Film properties on Glass | | | |
| Adhesion | 5B | 4B | 4B |
| Transmittance (% Min) | 83.82 | 83.88 | 84.05 |
| Haze (%) | 2.70 | 1.14 | 1.55 |
| Humidity | — | — | — |
| Appearance | non-tacky; very | slight bubbling; hazy | slight bubbling and |
| | slight blistering | watermarks | blistering; hazy |
| | | | watermarks |
| Adhesion | 3B | 4B | 0B |
| Transmittance (% Min) | 83.50 | 83.57 | 83.71 |
| Haze (%) | 4.99 | 8.95 | 5.07 |
| Free Film properties | | | |
| Instron | — | — | — |
| Young Modulus (MPa) | 15.18 | 9.84 | 8.47 |
| Elongation (%) | 102.46 | 100.31 | 61.48 |
| Tensile strength (MPa) | 9.52 | 6.24 | 3.14 |
| DMA | — | — | — |
| Tg (° C.) | 7 | 12 | 5 |
| Crosslink density | 0.48 | 0.91 | 1.12 |
| (mmoles/cc) | | | |
| MVTR | 140.65 | 31.66 | 53.38 |
| DFT (mils) | 3.31 | 19.13 | 16.40 |
| Permeance | 465 | 606 | 876 |

A total of 200.00 grams were prepared in a Flaktek mixing cup for examples 5a, 5b and 5c, individually. All three examples featured a two component system of a hydroxyl package and an isocyanate. The hydroxyl package would be prepared in the mixing cup first, with the polyol (resin) being added first and any hydroxyl additive (such as trimethylol propane, TMP) added second, to form a singular component. (If this component featured an additive, it could be mixed prior to the addition of the isocyanate component.) Once the hydroxyl package was prepared, the isocyanate would be added to the cup; generally the isocyanate component is warmed, for a lower, more workable viscosity. After the isocyanate had been added, the catalyst (dibutyltin dilaurate, DBTDL) would be added by pipette. Then the mixing cup would be sealed and placed into the D&Q mixing for 15 seconds at a spin speed of 3. As soon as the D&Q mixer had finished (and unlocked, following a 5 second safety delay), the mixture would be poured onto the transparency and glass substrate and drawn down using an 8 mil square.

Once the draw downs had been prepared, the samples were kept at room temperature for 24 hours and then were placed in a 140° F. hot room for an additional 24 hours. Upon removal, the samples were allowed to cool and then were prepared for testing. Glass samples were tested for transmittance (% minimum) and haze (%) using a XRight Color Eye 7 Spectrophotometer. The glass samples were then tested for adhesion by crosshatch adhesion testing then cut into a 2″×4″ sample. These pieces were placed into a humidity cabinet, 100° F. and 100% humidity, for 500 hours. The samples were then removed and allowed to dry overnight prior to transmittance, haze and adhesion measurements were taken again. Transparency films were peeled for free film testing. Narrow strips were cut for Instron SFL testing, to determine tensile strength (MPa), elongation (%) and Young's Modulus (MPa), and DMA 2980 testing, to determine crosslink density (mmoles/cc) and Tg (° C.). Free films were cut into a larger, circular or square sample for testing on the Lyssy L80-5000 Water Vapor Permeability Tester (for MVTR, Moisture Vapor Transfer Rate) to determine a permeance value for each sample.

### Example—6a

Polyurea fluid encapsulant formulations were prepared using the resins of Example 4 as follows.

TABLE 13
Polyurea Fluid Encapsulant

| | Example 6a |
|---|---|
| Components | |
| Isocyanate | 94.88 Ex. 4d |
| Amine | 10.52 Clearlink 1000 |
| | 73.66 Desmophen NH1420 |
| | 20.95 Jeffamine D2000 |
| Ratio (NCO/Amn) | 1.06 |
| Paint Properties | |
| Gel Point (minutes) | ~37 |
| Film properties on Glass | |
| Adhesion | 5B |
| Transmittance (% Min) | 87.19 |
| Haze (%) | 0.58 |
| Humidity | — |
| Appearance | — |
| Adhesion | 4B |
| Transmittance (% Min) | 87.15 |
| Haze (%) | 1.95 |
| Free Film properties | |
| Instron | — |
| Young Modulus (MPa) | 450.01 |
| Elongation (%) | 10.80 |
| Tensile strength (MPa) | 18.28 |
| DMA | — |
| Tg (° C.) | 65 |
| Crosslink density | 0.47 |
| (mmoles/cc) | |
| MVTR | 15.91 |
| DFT (mils) | 27.64 |
| Permeance | 440 |

A total of 200.00 grams were prepared in a Flaktek mixing cup for example 6a. The example featured a two component system of an amine package and an isocyanate. The amine package was prepared in the mixing cup first, with the amine(s) being added together to form a singular component. (This component could be mixed prior to the addition of the isocyanate component.) Once the amine package was prepared, the isocyanate was added to the cup; generally the isocyanate component is warmed, for a lower, more workable viscosity. Immediately following the addition of the isocyanate, the mixing cup was sealed and placed into the D&Q mixing for 15 seconds at a spin speed of 3. As soon as the D&Q mixer had finished (and unlocked, following a 5 second safety delay), the mixture was poured onto the transparency and glass substrate and drawn down using an 8 mil square.

Note for Examples 5a-5c and 6a shown in Tables 12 and 13: Isocyanate Ex. 4d was obtained in house Amines Clearlink 1000 and Jeffamine D2000 and SD231 were obtained from Huntsman. The amine Desmophen NH1420 and the isocyanate resins Desmodur XP2580 and Desmodur XP2410 were obtained from Bayer Material Science. Examples 4a, 4b, and 4c were obtained in house.

Protective back coatings were prepared as follows. Coating was sprayed by hand gun on aluminum or on a release film. Then it was cured at different conditions (room temperature for 7 days or 140F for 30 minutes) before any test. Narrow strips of film would be cut for DMA 2980 testing, to determine crosslink density (mmoles/cc) and Tg (° C.). Free films would also be cut into a larger, circular or square sample for testing on the Lyssy L80-5000 Water Vapor Permeability Tester (for MVTR, Moisture Vapor Transfer Rate) to determine a permeance value for each sample. Film on Aluminum was tested for crosshatch adhesion and volume resistivity by Dr. Thiedig. The results are shown in Table 14.

TABLE 14
Protective Coatings Examples

| | volume resistivity | Aluminum | Permeance | | crosslink |
|---|---|---|---|---|---|
| Name and curing | (Ω/cm) | adhesion | (g * mil/m² * day) | Tg (° C.) | density |
| DP40 primer, RT | >2 × 10¹² | 5B | 40 | 56 | 3.9 |
| DP40 primer, 140F | >2 × 10¹² | 5B | 35 | | |
| NCP270, RT | 1.4 × 10¹³ | 5B | 77 | 64 | 3.8 |
| NCP 270, 140F | 2.4 × 10¹³ | 5B | 65 | 68 | 25 |
| Envirobase, RT | 1.6 × 10¹⁴ | 5B | 67 | 53 | 11 |
| Envirobase, 140F | 4.1 × 10¹⁴ | 5B | 61 | 55 | 5.6 |
| CA7502 modified | 1.8 × 10¹³ | 5B | 51 | 64 | 3.8 |
| CA7502 modified | 8.6 × 10¹³ | 5B | 47 | | |
| Coraflon (RT) | | 5B | 80 | 43 | 1.5 |
| Coraflon | 1.9 × 10¹⁴ | 5B | 77 | 48 | 1.5 |
| polyurea A | 8.1 × 10¹² | 5B | 702 | 48 | 0.3 |
| polyurea B | 9.1 × 10¹² | 5B | 609 | 63 | 0.5 |

As described in the present disclosure, certain embodiments presented herein may address one or more disadvantages associated with the use of a vacuum lamination processes for the production of photovoltaic modules possess. For example, as set forth herein, the present processes may allow for continuous processing and improved production efficiency with the elimination of the vacuum lamination steps, as these latter processes are batch or semi-batch and labor-intensive. In addition, elimination of these steps eliminates the need for a vacuum lamination apparatus required to perform the vacuum lamination process, thereby reducing or eliminating capital-intensive equipment that significantly increases production time and costs. Furthermore, the application of vacuum pressure and compression pressure to laminate the photovoltaic cells in between the front transparency and the backsheet induces large mechanical stresses on the photovoltaic semiconducting material wafers comprising bulk photovoltaic cells. The semiconducting materials (e.g., crystalline silicon) are generally brittle and the constituent wafers can break under the induced mechanical stresses during the vacuum lamination process. This breakage problem is exacerbated when attempting to produce photovoltaic modules comprising relatively thin wafers, which more easily break under the mechanical stresses inherent in the vacuum lamination process. Elimination of vacuum lamination may reduce the mechanical stresses involved in the production process. Furthermore, elimination of the lamination of pre-formed backsheets and back side encapsulant material sheets to a photovoltaic cell/front glass may decrease the mass and volume of the resultant photovoltaic module. In addition, the coating compositions and their related coating systems or configurations of the present disclosure may provide one or more advantages, such as good durability, moisture barrier, abrasion resistance, and the like.

This specification has been written with reference to various non-limiting and non-exhaustive embodiments. However, it will be recognized by persons having ordinary skill in the art that various substitutions, modifications, or combinations of any of the disclosed embodiments (or portions thereof) may be made within the scope of this specification. Thus, it is contemplated and understood that this specification supports additional embodiments not expressly set forth herein. Such embodiments may be obtained, for example, by combining, modifying, or reorganizing any of the disclosed steps, step sequences, components, elements, features, aspects, characteristics, limitations, and the like, of the various non-limiting embodiments described in this specification. In this manner, Applicant reserves the right to amend the claims during prosecution to add features as variously described in this specification, and such amendments comply with written description support requirements.

1. A photovoltaic module comprising:
a front transparency;
a fluid encapsulant deposited on at least a portion of the front transparency;
electrically interconnected photovoltaic cells positioned on the fluid encapsulant; and
a topcoat deposited on at least a portion of the electrically interconnected photovoltaic cells.

2. The photovoltaic module of claim 1, wherein the fluid encapsulant comprises a polyurethane resin, a polyurea resin or a hybrid polyurethane-polyurea resin.

3. The photovoltaic module of claim 1, wherein the fluid encapsulant comprises 50 to 100 percent solids coating composition.

4. The photovoltaic module of claim 1, wherein the fluid encapsulant comprises a liquid silicone coating.

5. The photovoltaic module of claim 1, wherein the photovoltaic cells comprise crystalline silicon wafers.

6. The photovoltaic module of claim 1, wherein the topcoat comprises inorganic particles.

7. The photovoltaic module of claim 1, wherein the topcoat comprises polyepoxide and polyamine.

8. The photovoltaic module of claim 1, further comprising a primer positioned between the topcoat and the electrically interconnected photovoltaic cells.

9. The photovoltaic module of claim 8, wherein the primer comprises epoxy, polyurethane, ketimine, cyclic carbonate and/or polyaspartate coating.

10. The photovoltaic module of claim 1, farther comprising a second fluid encapsulant positioned between the electrically interconnected photovoltaic cells and the topcoat.

11. The photovoltaic module of claim 10, further comprising a primer positioned between the second fluid encapsulant and the topcoat.

12. A method for the production of a photovoltaic module comprising:
applying fluid encapsulant to at least a portion of a front transparency;
applying photovoltaic cells and electrical interconnections on the fluid encapsulant wherein the cells are electrically connected;
applying a topcoat to at least a portion of the photovoltaic cells and electrical interconnections; and
curing the topcoat.

13. The method of claim 12, further comprising curing the fluid encapsulant after applying the electrically interconnected photovoltaic cells and before applying the topcoat.

14. The method of claim 12, comprising simultaneously curing the fluid encapsulant and the topcoat.

15. The method of claim 12, further comprising applying a primer to at least a portion of the photovoltaic cells and electrical interconnections, and applying the topcoat onto the primer.

16. The method of claim 15, further comprising curing the primer before applying the topcoat.

17. The method of claim 15, comprising simultaneously curing the primer and the topcoat.

18. The method of claim 12, further comprising applying a second fluid encapsulant to at least a portion of the photovoltaic cells and electrical interconnections prior to applying the topcoat.

19. The method of claim 18, farther comprising applying a primer to at least a portion of the second fluid encapsulant, and applying the topcoat onto the primer.

20. A photovoltaic module produced in accordance with the method of claim 12.

21. The photovoltaic module of claim 1, wherein the topcoat comprises polyurea.
